(19) United States
(12) Patent Application Publication
(10) Pub. No.: US 2025/0309022 A1
(43) Pub. Date: Oct. 2, 2025

(54) ANNULAR STRESS REDUCTION STRUCTURE FOR SEMICONDUCTOR SUBSTRATE

(71) Applicant: Micron Technology, Inc., Boise, ID (US)

(72) Inventors: Wen Ju LIU, Kaohsiung (TW); Chien Ming CHEN, Taichung (TW); Chong Leong GAN, Taichung (TW)

(21) Appl. No.: 19/061,903

(22) Filed: Feb. 24, 2025

Related U.S. Application Data
(60) Provisional application No. 63/570,549, filed on Mar. 27, 2024.

(51) Int. Cl. H01L 23/31; H01L 21/02; H01L 21/306; H01L 21/56; H01L 23/14; H01L 23/29; H01L 25/18; H10B 80/00

(52) U.S. Cl. CPC H01L 23/3192; H01L 21/02529; H01L 21/02631; H01L 21/30625; H01L 21/56; H01L 23/147; H01L 23/291; H01L 23/293; H01L 23/3171; H01L 25/18; H10B 80/00

(57) ABSTRACT

Implementations described herein relate to various semiconductor device assemblies. In some implementations, a semiconductor substrate includes an array of semiconductor dies a polyimide layer over the array of semiconductor dies, and a nitride layer between the array of semiconductor dies and the polyimide layer. The semiconductor substrate further includes a stress reduction structure that is along an outer perimeter of the semiconductor substrate, that surrounds the array of semiconductor dies, and that penetrates through the nitride layer.

### CROSS REFERENCE TO RELATED APPLICATION

This patent application claims priority to U.S. Provisional Patent Application No. 63/570,549, filed on Mar. 27, 2024, and entitled “ANNULAR STRESS REDUCTION STRUCTURE FOR SEMICONDUCTOR SUBSTRATE.” The disclosure of the prior application is considered part of and is incorporated by reference into this patent application.

### TECHNICAL FIELD

The present disclosure generally relates to semiconductor devices and methods of forming semiconductor devices. For example, the present disclosure relates to an annular stress reduction structure for a semiconductor substrate.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 includes a diagrammatic side section view of examples of an implementation of a stress reduction structure described herein.

FIG. 4 includes a diagrammatic side section view of an implementation of a stress reduction structure described herein.

FIG. 5 is a flowchart of an example method of forming a semiconductor substrate having an annular stress reduction structure described herein.

FIG. 6 is a flowchart of an example method of forming a substrate having an annular stress reduction structure described herein.

FIG. 7 is a flowchart of an example method of forming an integrated assembly or memory device described herein.

FIG. 8A through FIG. 8G are diagrammatic views showing formation of an annular stress reduction structure described at stages of an example process described herein.

### DETAILED DESCRIPTION

A semiconductor substrate (e.g., a wafer) serves as a foundational platform for the creation of semiconductor dies, which are crucial components in electronic devices. Typically composed of silicon, the semiconductor substrate may undergo intricate processes like doping, etching, and deposition to form integrated circuits. Conductive layers (e.g., films), often made of materials like aluminum or copper, are deposited onto the substrate to facilitate electron flow and create connections for integrated circuitry. Dielectric layers (e.g., films), such as silicon dioxide or silicon nitride, are also formed on the substrate to insulate and isolate different parts of the integrated circuitry. Through photolithography and other fabrication techniques, intricate patterns are etched onto the substrate, defining the layout and integrated circuitry of the semiconductor dies.

The deposition and formation of the conductive and/or dielectric layers on the semiconductor substrate can cause the semiconductor substrate to warp and/or bow. Variations in stress during the deposition process, differences in coefficients of thermal expansion between materials, and uneven layer thickness can all contribute to warpage and/or bowing of the semiconductor substrate.

A semiconductor package including an advanced semiconductor product, such as managed NAND or high bandwidth memory (HBM), may include a stack of semiconductor dies from the semiconductor substrate. In some cases, individual semiconductor dies from the semiconductor substrate may, during assembly of the semiconductor die package, fail to satisfy a coplanarity threshold and encounter defects such as delamination, peeling, and/or misalignment with other semiconductor dies. The delamination, peeling, and/or misalignment defects may reduce a quality and/or a reliability of the semiconductor package.

Some implementations described herein include an annular stress reduction structure for a semiconductor substrate. The annular stress reduction structure, which includes a porous silicon carbide ring that is formed in a trench along a perimeter of the semiconductor substrate, may reduce stresses and/or strains in a stack of conductive and/or dielectric layers across semiconductor substrate. Reducing the stresses and/or strains in the stack of conductive and/or dielectric layers may, in turn, reduce warpage and/or bowing of the semiconductor substrate.

In this way, individual semiconductor dies from the semiconductor substrate may satisfy a coplanarity threshold that is essential to assembly of a semiconductor package including stacked semiconductor dies. By satisfying the coplanarity threshold, defects such as delamination, peeling, and/or misalignment with other semiconductor dies may be reduced to improve a quality and/or a reliability of the semiconductor die package. Improving the quality and/or reliability of the semiconductor package may reduce an amount of resources (e.g., semiconductor manufacturing tools, labor, raw materials, and/or computing resources) used to support a market consuming the semiconductor package.

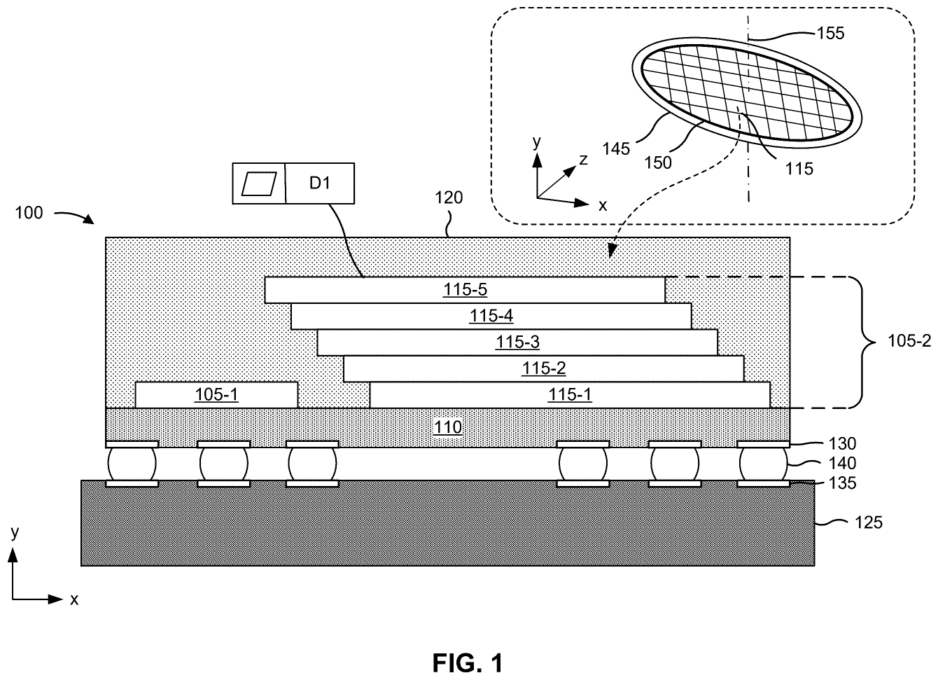

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in the side section view of FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a shingle stack (e.g., with die edges that are not aligned, which provides space for wire bonding near the edges of the dies 115), in some implementations, the dies 115 may be stacked in a different arrangement, such as a straight stack (e.g., with aligned die edges).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher-level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

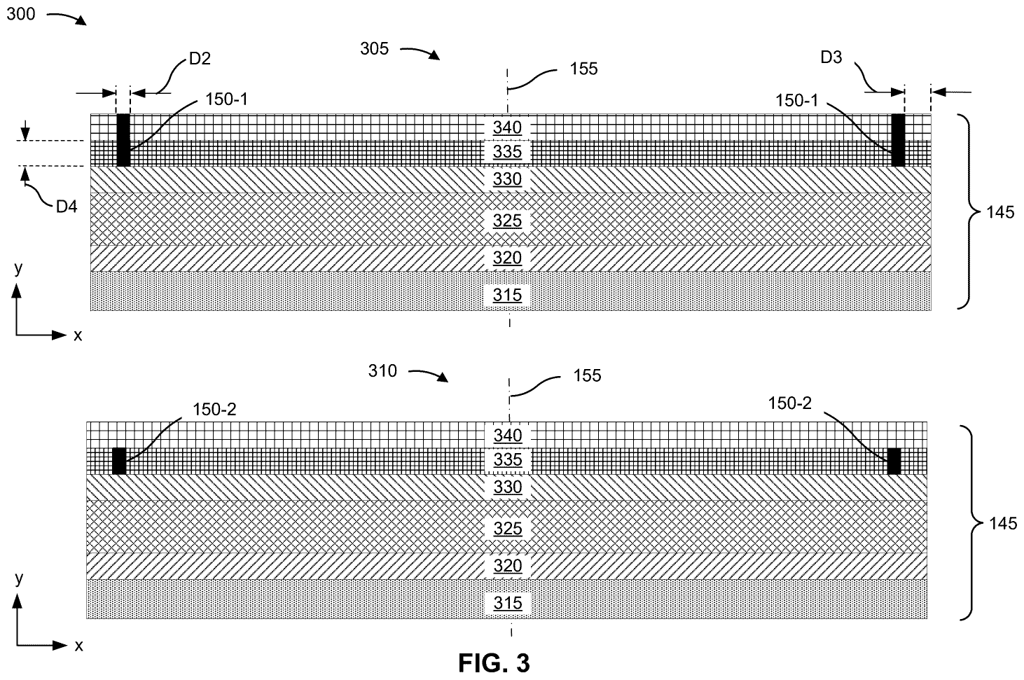

As shown in the isometric view in the upper right portion of FIG. 1, the dies 115 may be formed on a semiconductor substrate 145 (e.g., a silicon wafer). The semiconductor substrate 145 (and/or the dies 115) may have a combination of semiconductive, conductive, and dielectric layers (e.g., films) that, due to differences in mechanical properties such as coefficients of thermal expansion and moduli of elasticity, cause lateral stresses across the semiconductor substrate 145 and cause warpage and/or bowing of the semiconductor substrate 145. However, as described in greater detail in connection with FIG. 3 through FIG. 8G, the semiconductor substrate 145 may include a stress reduction structure 150. The stress reduction structure 150 may be annular (e.g., ring-shaped) about a central axis 155 of the semiconductor substrate. Furthermore, the stress reduction structure 150 may be proximate and/or along a perimeter of the semiconductor substrate 145 (e.g., in an exclusion zone that does not include any portion of the dies 115). The stress reduction structure 150 may alleviate, mitigate, and/or reduce lateral stresses across the semiconductor substrate 145 to reduce warpage and/or bowing of the semiconductor substrate 145. By reducing the warpage and or bowing of the substrate, a coplanarity D1 of one or more of the dies 115 may be maintained to satisfy a coplanarity threshold and reduce a likelihood of delamination, peeling, and/or misalignment defects.

As indicated above, FIG. 1 is provided as an example. Other examples may differ from what is described with regard to FIG. 1.

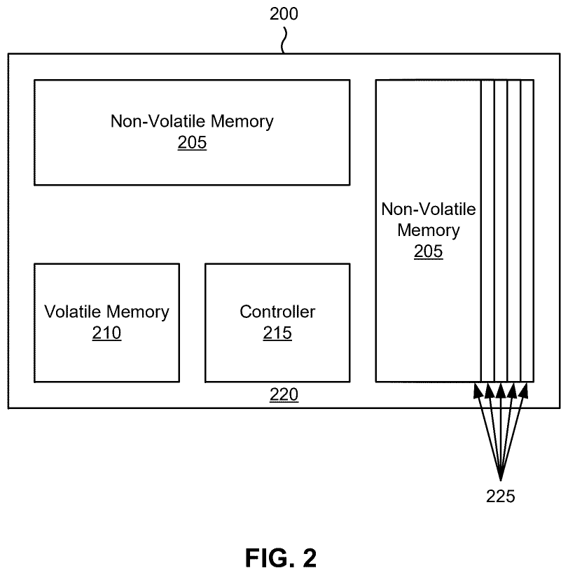

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

The memory device 200 may include one or more of the dies 115 of FIG. 1. Furthermore, and as described in greater detail in connection with FIG. 3 through FIG. 8G, the dies 115 may have one or more features related to the stress reduction structure 150 of FIG. 1.

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

FIG. 3 includes a diagrammatic side section view of examples of an implementation 300 of a stress reduction structure (e.g., the stress reduction structure 150) described herein. The upper portion of FIG. 3 includes an example 305 of the stress reduction structure 150-1 in the semiconductor substrate 145. The lower portion of FIG. 3 includes an example 310 of the stress reduction structure 150-2 in the semiconductor substrate 145. The stress reduction structure 150-1 and the structure stress reduction structure 150-2 may each, from a top-view perspective, be annular (e.g., be ring-shaped) about the central axis 155 of the substrate 145. Additionally, or alternatively, the stress reduction structure 150-1 and the structure stress reduction structure 150-2 may each have an approximately rectangular cross-section.

The semiconductor substrate 145 of FIG. 3 may include a combination of layers (e.g., films) that form structures and/or features included as part of the semiconductor substrate 145. The combinations of layers may include layers of semiconductive materials, dielectric materials, and/or conductive materials.

A semiconductive material may comprise, consist of, or consist essentially of silicon (e.g., polysilicon or polycrystalline silicon). Alternatively, and in some implementations, a semiconductive material consists of, or consists essentially of, silicon carbide, gallium nitride, a type III-V element, porous silicon carbide, or another suitable semiconductive material, among other examples.

A conductive material may be an electrical conductor and may comprise, consist of, or consist essentially of conductive material. As used herein, a “conductive material” may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), or another suitable conductive material, among other examples.

A dielectric material may be electrical insulator and may comprise, consist of, or consist essentially of insulative material. As used herein, an “insulative material” may comprise, consist of, or consist essentially of an oxide (e.g., silicon oxide, aluminum oxide, or another suitable oxide material), a nitride (e.g., silicon nitride aluminum nitride, or another suitable nitride material), polyimide, or another suitable insulative material, among other examples.

Layers of semiconductive materials, dielectric materials, and/or conductive materials may combine to form different regions of the semiconductor substrate 145. For example, the semiconductor substrate 145 may include a substrate region 315. The substrate region 315 may include one or more layers of a semiconductive material as described above.

Additionally, or alternatively and as shown in FIG. 3, the semiconductor substrate 145 may include an integrated circuit (IC) region 320 that is over and/or on the substrate region 315. The IC region 320 may include integrated circuitry that is formed from one or more layers of semiconductive materials, dielectric materials, and/or conductive materials as described above.

Additionally, or alternatively, and as shown in FIG. 3, the semiconductor substrate 145 may include a pillar region 325 that is over and/or on the IC region 320. The pillar region 325 may include pillar structures that are formed from one or more layers of semiconductive materials, dielectric materials, and/or conductive materials as described above. In some implementations, the pillar structures correspond to memory cells of a NAND memory device.

Additionally, or alternatively, and as shown in FIG. 3, the semiconductor substrate 145 may include an interconnect region 330 (e.g., a backend of line (BEOL) region) that is over and/or on the pillar region 325. The interconnect region 330 may include one or more layers of semiconductive materials, dielectric materials, and/or conductive materials as described above. In some implementations, the interconnect region 330 includes traces and/or redistribution layers that provide an electrical path and/or connectivity from underlying regions to contacts and/or electrical connections that are external to the semiconductor substrate 145 (e.g., external to the dies 115 that may be included in the apparatus 100).

Additionally, or alternatively and as shown in FIG. 3, the semiconductor substrate 145 may include a passivation region 335 that is over and/or on the interconnect region 330. The passivation region 335 may include one or more layers of a dielectric material as described above. In some implementations, the passivation region 335 provides electrical isolation to integrated circuitry and/or electrically conductive structures included in underlying regions.

Additionally, or alternatively and as shown in FIG. 3, the semiconductor substrate 145 may include a protective region 340 that is over and/or on the passivation region 335. The protective region 340 may include one or more layers of a polymer material. In some implementations, the protective region 340 includes one or more layers of polyimide. In some implementations, the protective region 340 safeguards underlying regions from chemical contamination, moisture, and/or mechanical damage.

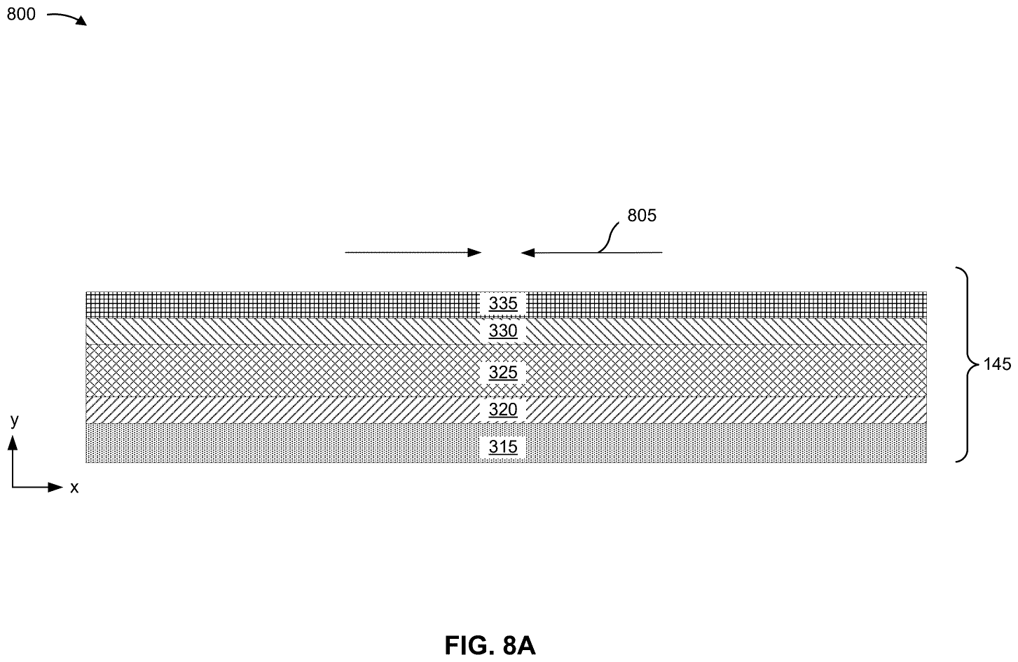

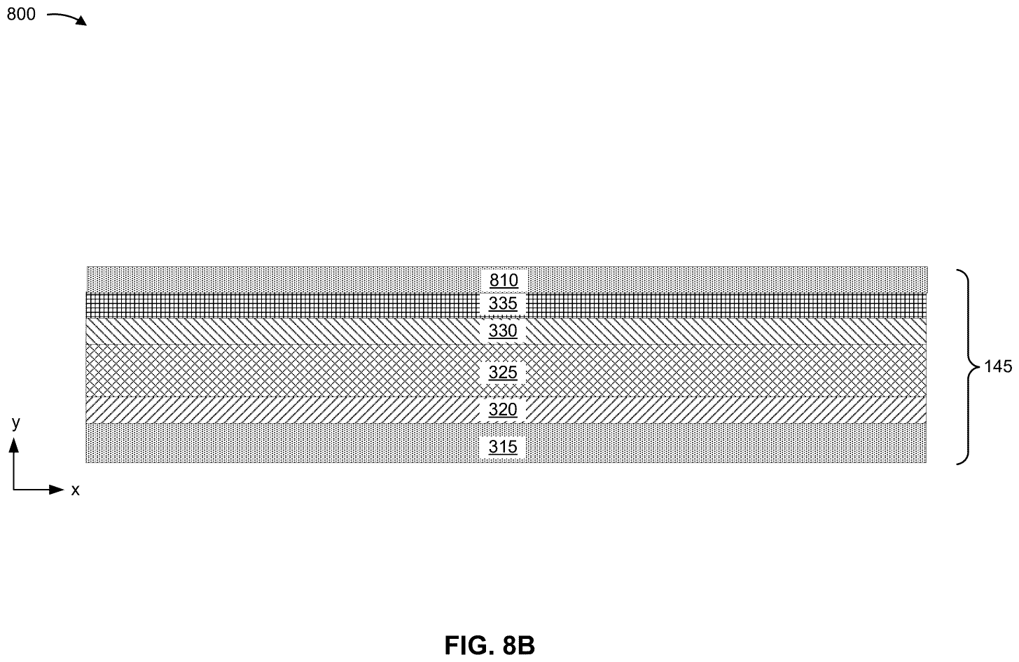

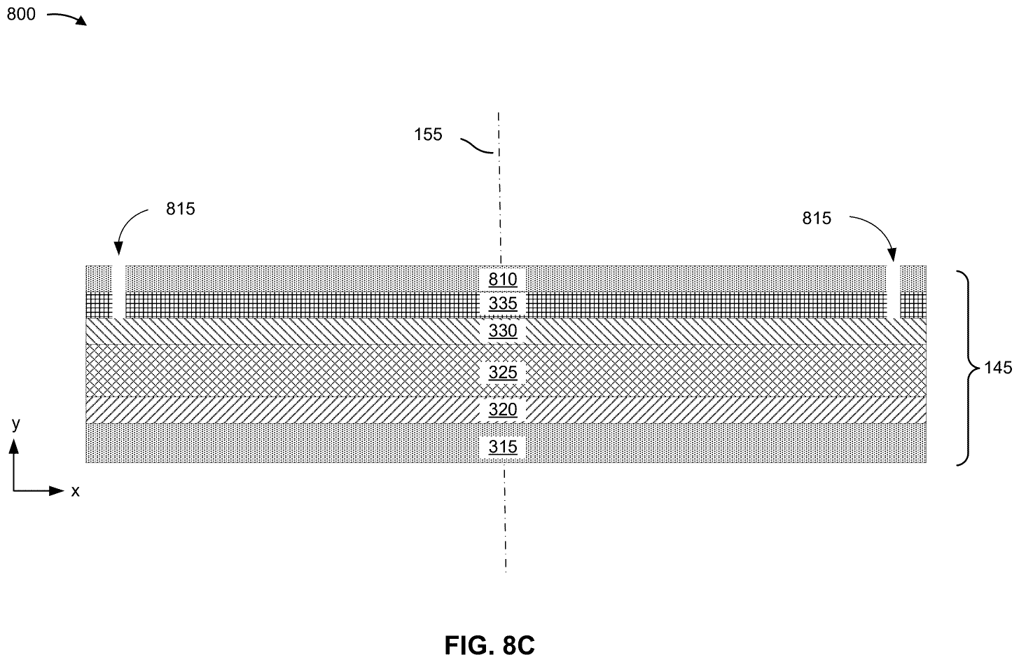

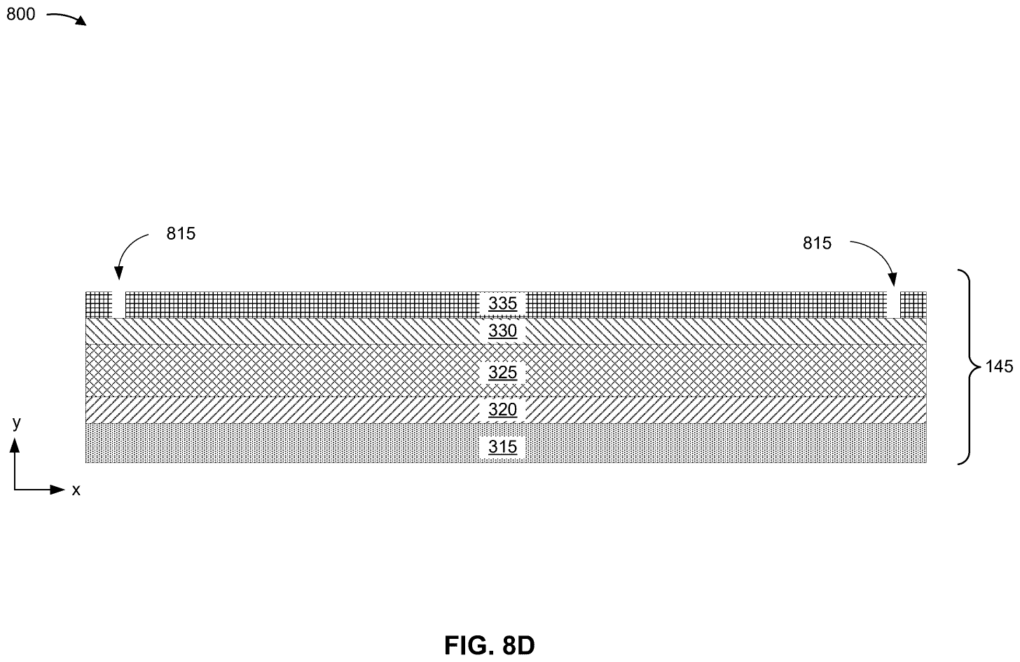

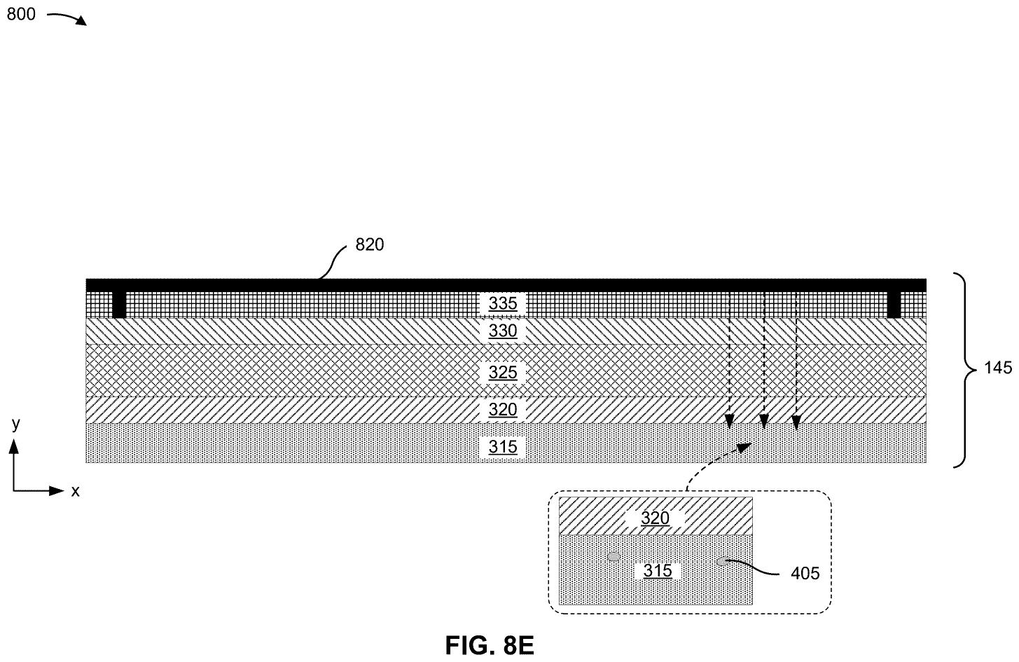

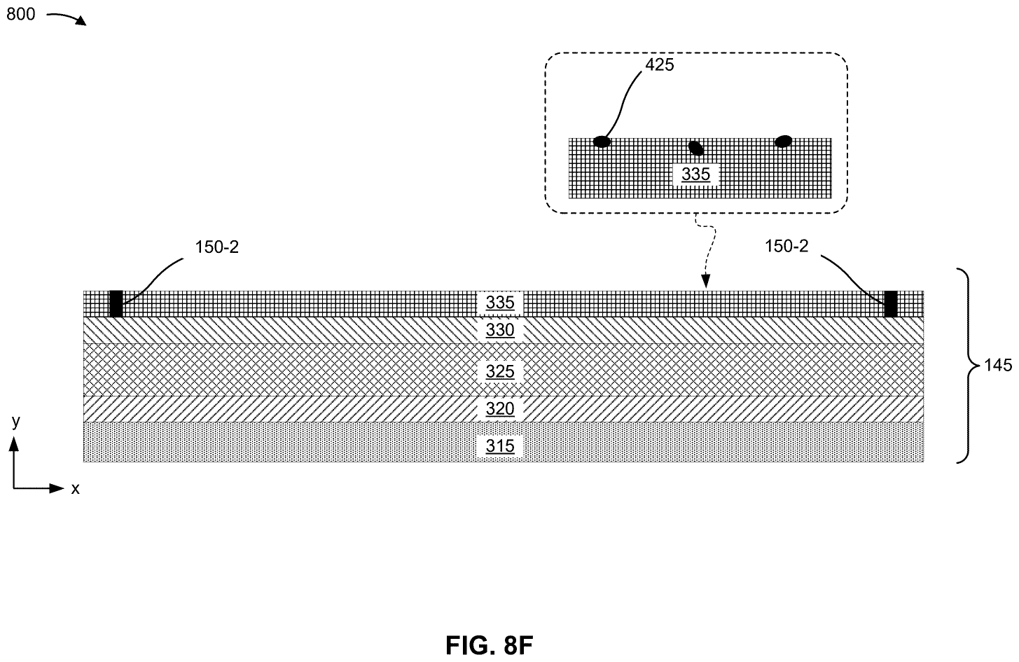

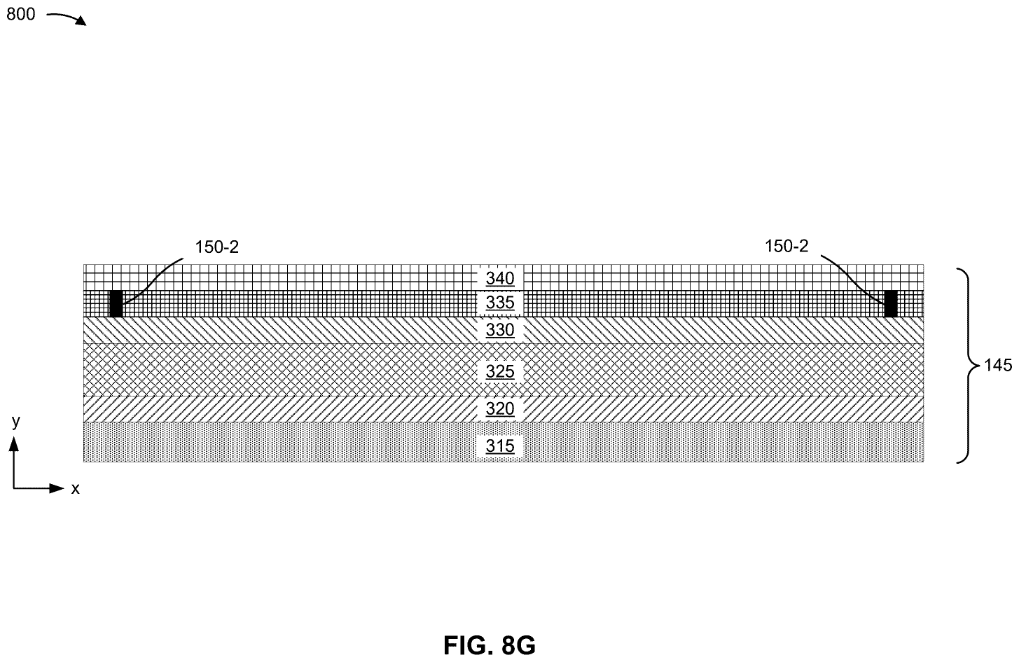

As shown in FIG. 3, the semiconductor substrate 145 includes a stress reduction structure 150 that is proximate (e.g., along) a perimeter (e.g. along a periphery and/or over an exclusion zone) of the semiconductor substrate 145. In some implementations, the stress reduction structure is over and/or on the interconnect region 330. The stress reduction structure 150 may include one or more layers of a semiconductive material as described above. For example, and in some implementations, the stress reduction structure 150 includes one or more layers of porous silicon carbide. As described in greater detail in connection with FIG. 8A through FIG. 8G, the stress reduction structure 150, and techniques to form the stress reduction structure 150, may alleviate stresses across the semiconductor substrate 145 to reduce warpage and/or bowing.

The stress reduction structure 150 may include different configurations. For example, the stress reduction structure 150-1 (e.g., example 305) penetrates through the protective region 340 and the passivation region 335. Further, and as shown in FIG. 3, the stress reduction structure 150-1 may be exposed at a top surface of the protective region 340.

However, and in an alternate configuration, the stress reduction structure 150-2 (e.g., example 310) is embedded in the passivation region 335 below the protective region 340. In other words, the stress reduction structure 150-2 penetrates through the passivation region 335 and not the passivation region (e.g., the stress reduction structure 150-2 is captured within layering of the semiconductor substrate 145). Furthermore, the stress reduction structure 150-2 is not exposed.

The stress reduction structure 150 may include a combination of geometric properties and/or relationships. For example, a width D2 of the stress reduction structure 150-1 (and/or the stress reduction structure 150-2) may be included in a range of approximately 18 microns (μm) to approximately 22 μm. Additionally, or alternatively, a distance D3 from an edge of the stress reduction structure 150-1 (and/or the stress reduction structure 150-2) to an edge of the semiconductor substrate 145 may be included in a range of approximately 3.1 millimeters (mm) to approximately 3.9 mm. However, other values and ranges for the width D2 and the distance D3 are within the scope of the present disclosure.

Additionally, or alternatively, and as shown in FIG. 3, the passivation region 335 may include a thickness D4. Using thin film mechanics relationships such as the Stoney equation, a thickness D4 may be determined such that dies (e.g., the dies 115) from the semiconductor substrate 145 have a coplanarity (e.g., the coplanarity D1) that satisfies a threshold needed for stacking the dies in a semiconductor package (e.g., the apparatus 100). For example, and for a case in which the passivation region 335 includes nitride, the Stoney equation may be used to determine that the thickness D4 may be reduced (e.g., thinned) to approximately 50% of a thickness of a passivation region of another semiconductor substrate yielding dies without such coplanarity needs. Additionally, or alternatively, the Stoney equation may be used to determine that the thickness D4 is included in a range of approximately 0.4 μm to approximately 0.6 μm.

If the thickness D4 is less than approximately 0.4 μm, the passivation region 335 may not provide sufficient electrical isolation to underlying circuitry of the semiconductor substrate 145. If the thickness D4 is between approximately 0.4 μm and approximately 0.6 μm, the passivation region 335 may provide sufficient electrical isolation to underlying circuitry of the semiconductor substrate 145. Additionally, or alternatively, lateral compressive stresses in the passivation region 335 may be reduced such that bowing and/or warpage of the semiconductor substrate 145 satisfies a threshold. If the thickness D4 is greater than approximately 0.6 μm, the lateral compressive stresses within the passivation region 335 may be increased such that bowing and/or warpage of the semiconductor substrate fails to satisfy a threshold. However, other values and ranges for the thickness D4 are within the scope of the present disclosure.

As indicated above, FIG. 3 is provided as an example. Other examples may differ from what is described with regard to FIG. 3.

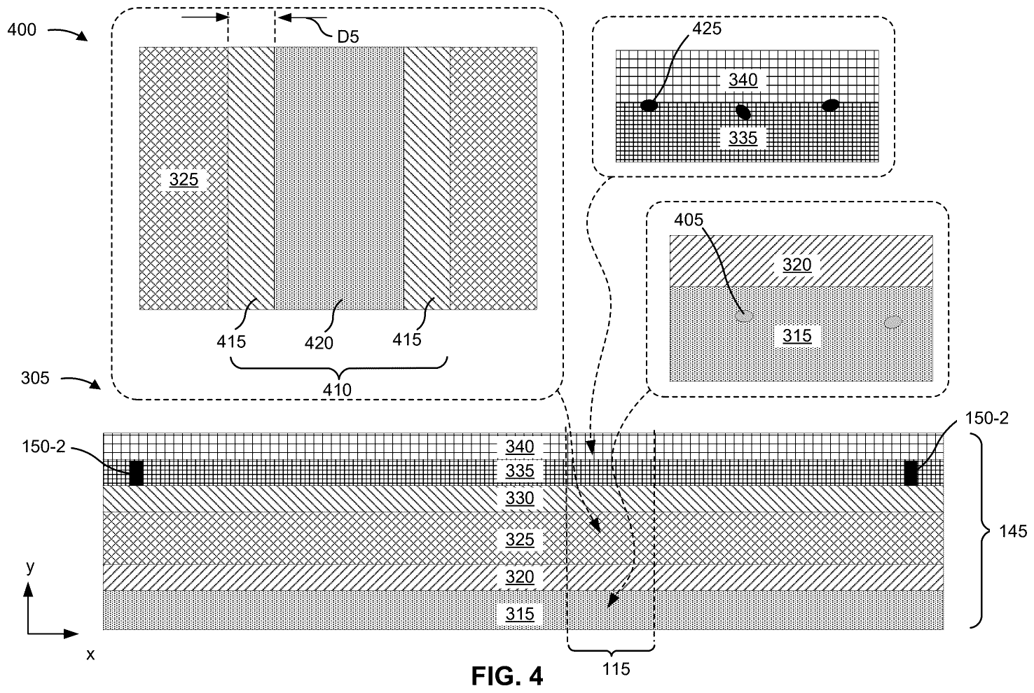

FIG. 4 includes a diagrammatic side section view of an implementation 400 of a stress reduction structure (e.g., the stress reduction structure 150-2) described herein. FIG. 4 shows and describes additional features and/or aspects that may be present in individual dies 115 and or the semiconductor substrate 145. Although FIG. 4 shows and describes the features and/or aspects in the context of the stress reduction structure 150-2, the features and/or aspects may be found in the stress reduction structure 150-1 and/or other similar stress reduction structures. The additional features and/or aspects may be formed as a result of using techniques as described in greater detail in connection with FIGS. 8A-8G.

As shown in FIG. 4, the substrate region 315 may include nanocrystal structures 405. For example, and in some implementations, the substrate region 315 includes silicon and the stress reduction structure 150-2 includes porous silicon carbide. In such implementations, and during a deposition operation that deposits a layer of porous silicon carbide as part of forming the stress reduction structure 150-2, a diffusivity property may cause diffusion of the porous silicon carbide into the substrate region 315. Porous silicon carbide that diffused into the substrate region 315 may interact with voids in the substrate region 315 to form (e.g., epitaxially grow) the nanocrystal structures 405 (e.g., porous silicon carbide nanocrystal structures).

Additionally, or alternatively, and as shown in FIG. 4, the pillar region 325 may include one or more pillar structures 410 that correspond to memory cells of a NAND memory device. In some implementations, the pillar structures 410 include a liner layer 415 and a core structure 420, where the liner layer 415 includes nitride and the core structure 420 includes a dielectric material. In such implementations, a thickness D5 of the liner layer 415 may be included in a range of approximately 0.4 μm to approximately 0.6 μm.

If the thickness D5 is less than approximately 0.4 μm, the liner layer 415 may not provide sufficient electrical isolation between word lines and/or floating gate structures that couple with the core structure 420. If the thickness D5 is between approximately 0.4 μm and approximately 0.6 μm, the liner layer 415 may provide sufficient electrical isolation between word lines and/or floating gate structures that couple with the core structure 420. Additionally, or alternatively, vertical compressive stresses in the liner layer 415 may be reduced such that a contribution by the vertical compressive stresses to bowing and/or warpage of the semiconductor substrate 145 is negligible. If the thickness D5 is greater than approximately 0.6 μm, the vertical compressive stresses within the liner layer 415 may be increased such that the contribution by the vertical compressive stresses to bowing and/or warpage of the semiconductor substrate 145 is significant. However, other values and/or ranges for the thickness D5 are within the scope of the present disclosure.

Additionally, or alternatively and as shown in FIG. 4, composite particulates 425 may be proximate to an interface between the passivation region 335 and the protective region 340. In some implementations, not shown in FIG. 4, the composite particulates 425 are proximate a top surface of the protective region 340.

As noted, the stress reduction structure 150-2 may include porous silicon carbide. In such implementations, and during a chemical mechanical planarization (CMP) operation that planarizes a deposited layer of the porous silicon carbide as part of forming the stress reduction structure 150-2, the composite particulates 425 may be formed from the porous silicon carbide and one or more compound elements in the slurry. In a case where the slurry includes aluminum oxide, as an example, the composite particulates 425 may include composite particulates porous silicon carbide and aluminum oxide.

As indicated above, FIG. 4 is provided as an example. Other examples may differ from what is described with regard to FIG. 4.

As described in connection with FIG. 1 through FIG. 4, and in some implementations, a semiconductor substrate (e.g., the semiconductor substrate 145) includes an array of semiconductor dies (e.g., the dies 115), a polyimide layer (e.g., the protective region 340) over the array of semiconductor dies, a nitride layer (e.g., the passivation region 335) between the array of semiconductor dies and the polyimide layer, and a stress reduction structure (e.g., the stress reduction structure 150) that is along an outer perimeter of the semiconductor substrate, that surrounds the array of semiconductor dies, and that penetrates through the nitride layer.

Additionally, or alternatively and in some implementations, an integrated assembly (e.g., the apparatus 100 or the memory device 200) includes a substrate (e.g., the substrate 110) and a semiconductor die (e.g., the dies 115) over the substrate. The semiconductor die includes a passivation region (e.g., the passivation region 335) including a dielectric material (e.g., nitride), a protective region (e.g., the protective region 340) on the passivation region including a polymer material (e.g., polyimide), and a substrate region (e.g., the substrate region 315). In some implementations, composite particulates (e.g., the composite particulates 425) proximate an interface joining the passivation region and the protective region include one or more compound elements (e.g., silicon nitride and/or aluminum dioxide) that are absent from the polymer material and the dielectric material.

In these ways, individual semiconductor dies from the semiconductor substrate may satisfy coplanarity thresholds that are essential to assembly of a semiconductor package including stacked semiconductor dies. By satisfying the coplanarity threshold, defects such as delamination, peeling, and/or misalignment with other semiconductor dies may be reduced to improve a quality and/or a reliability of the semiconductor die package. Improving the quality and/or reliability of the semiconductor package may reduce an amount of resources (e.g., semiconductor manufacturing tools, labor, raw materials, and/or computing resources) used to support a market consuming the semiconductor package.

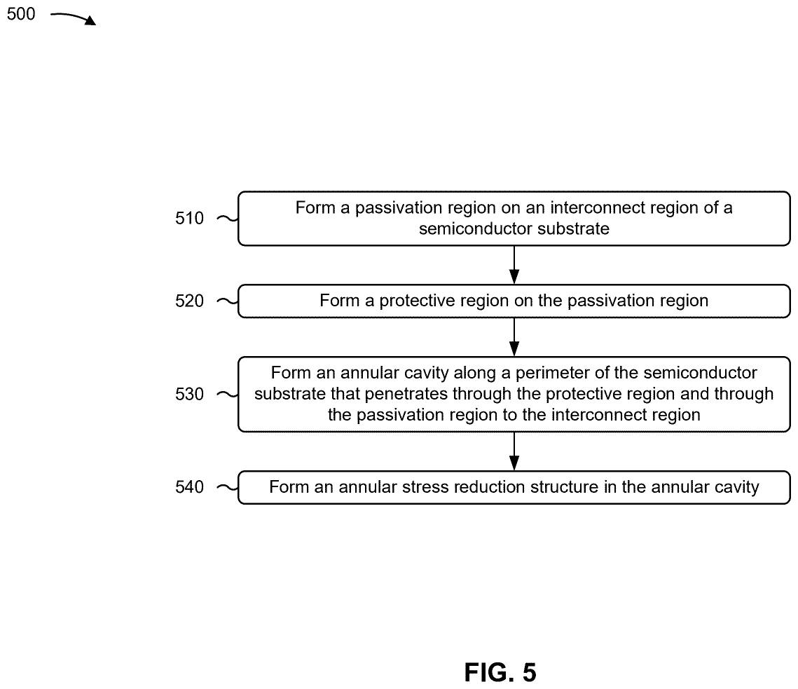

FIG. 5 is a flowchart of an example method 500 of forming a semiconductor substrate (e.g., the semiconductor substrate) having an annular stress reduction structure (e.g., the stress reduction structure 150-1 described in connection with example 305 of FIG. 3) described herein. In some implementations, and as described in greater detail in connection with FIGS. 8A-8G, one or more process blocks of FIG. 5 may be performed by various semiconductor manufacturing equipment.

As shown in FIG. 5, the method 500 may include forming a passivation region (e.g., the passivation region 335) on an interconnect region (e.g., the interconnect region 330) of a semiconductor substrate (e.g., the semiconductor substrate 145) (block 510). As further shown in FIG. 5, the method 500 may include forming a protective region (e.g., the protective region 340) on the passivation region (block 520). As further shown in FIG. 5, the method 500 may include forming an annular cavity along a perimeter of the semiconductor substrate that penetrates through the protective region and through the passivation region to the interconnect region (block 530). As further shown in FIG. 5, the method 500 may include forming an annular stress reduction structure (e.g., the stress reduction structure 150-1) in the annular cavity (block 540).

The method 500 may include additional aspects, such as any single aspect or any combination of aspects described below and/or in connection with one or more other methods described elsewhere herein.

In a first aspect, forming the passivation region includes forming a nitride layer and forming the protective region includes forming a polyimide layer.

In a second aspect, alone or in combination with the first aspect, forming the annular cavity includes forming a layer of photoresist on the protective region, forming a pattern of the annular cavity in the layer of photoresist, and removing material from the protective region according to the pattern to form the annular cavity.

In a third aspect, alone or in combination with one or more of the first and second aspects, forming the annular stress reduction structure in the annular cavity includes forming a layer of porous silicon carbide on the protective region. In some implementations, forming the layer of porous silicon carbide fills the annular cavity with porous silicon carbide.

In a fourth aspect, alone or in combination with one or more of the first through third aspects, forming the layer of porous silicon carbide includes forming the layer of porous silicon carbide using a physical vapor deposition operation.

In a fifth aspect, alone or in combination with one or more of the first through fourth aspects, the method 500 includes planarizing the layer of porous silicon carbide to expose a surface of the passivation region.

In a sixth aspect, alone or in combination with one or more of the first through fifth aspects, planarizing the layer of porous silicon carbide includes planarizing the layer of porous silicon oxide using a CMP operation that uses a slurry.

In a seventh aspect, alone or in combination with one or more of the first through sixth aspects, planarizing the layer of porous silicon carbide includes forming composite particulates (e.g., the composite particulates 425) proximate the surface of the passivation region. In some implementations, the composite particulates include porous silicon carbide combined with a compound element of the slurry.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the stress reduction structure 150-1, an integrated assembly that includes the structure stress reduction structure 150-1, any part described herein of the stress reduction structure 150-1, and/or any part described herein of an integrated assembly that includes the stress reduction structure 150-1. For example, the method 500 may include forming one or more of the apparatus 100, the dies 115, semiconductor the semiconductor substrate 145, and/or or the memory device 200.

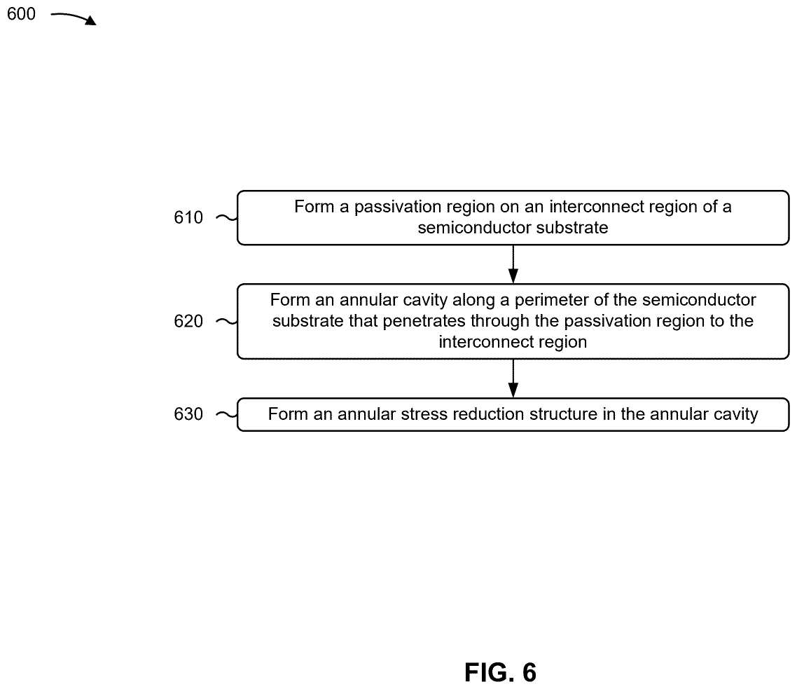

FIG. 6 is a flowchart of an example method 600 of forming a substrate having a stress reduction structure (e.g., the stress reduction structure 150-2 described in connection with example 310 of FIG. 3) described herein. In some implementations, one or more process blocks of FIG. 6 may be performed by various semiconductor manufacturing equipment.

As shown in FIG. 6, the method 600 may include forming a passivation region (e.g., the passivation region 335) on an interconnect region (e.g., the interconnect region 330) of a semiconductor substrate (block 610). As further shown in FIG. 6, the method 600 may include forming an annular cavity along a perimeter of the semiconductor substrate that penetrates through the passivation region to the interconnect region (block 620). As further shown in FIG. 6, the method 600 may include forming an annular stress reduction structure (e.g., the stress reduction structure 150-2) in the annular cavity (block 630).

The method 600 may include additional aspects, such as any single aspect or any combination of aspects described below and/or in connection with one or more other methods described elsewhere herein.

In a first aspect, forming the annular stress reduction structure includes forming a layer of semiconductive material (e.g., silicon carbide) on the passivation region.

In a second aspect, alone or in combination with the first aspect, forming the annular stress reduction structure includes planarizing the layer of semiconductive material using a chemical mechanical planarization operation that uses a slurry including aluminum dioxide.

In a third aspect, alone or in combination with one or more of the first and second aspects, forming the layer of semiconductive material on the passivation region includes forming the layer of semiconductive material using a deposition operation that diffuses atoms from the layer of semiconductive material into an underlying substrate region (e.g., the substrate region 315) to form nanocrystal structures (e.g., the nanocrystal structures 405) in the underlying substrate region.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the stress reduction structure 150-2, an integrated assembly that includes the structure stress reduction structure 150-2, any part described herein of the stress reduction structure 150-2, and/or any part described herein of an integrated assembly that includes the stress reduction structure 150-2. For example, the method 600 may include forming one or more of the apparatus 100, the dies 115, semiconductor the semiconductor substrate 145, and/or or the memory device 200.

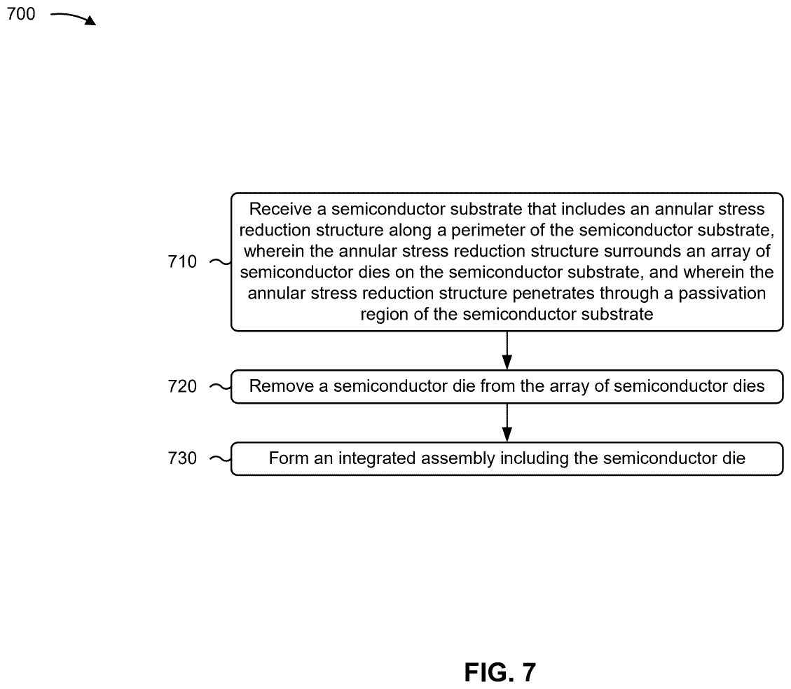

FIG. 7 is a flowchart of an example method 700 of forming an integrated assembly (e.g., the apparatus 100) or memory device (e.g., memory device 200) having an annular stress reduction structure (e.g., the stress reduction structure 150) described herein. In some implementations, one or more process blocks of FIG. 7 may be performed by various semiconductor manufacturing equipment.

As shown in FIG. 7, the method 700 may include receiving a semiconductor substrate (e.g., the semiconductor substrate 145) that includes an annular stress reduction structure (e.g., the stress reductions structure 150) along a perimeter of the semiconductor substrate, where the annular stress reduction structure surrounds an array of semiconductor dies (e.g., the dies 115) on the semiconductor substrate, and where the annular stress reduction structure penetrates through a passivation region (e.g., the passivation region 335) of the semiconductor substrate (block 710). As further shown in FIG. 7, the method 700 may include removing a semiconductor die from the array of semiconductor dies (block 720). As further shown in FIG. 7, the method 700 may include forming an integrated assembly (e.g., the apparatus 100 or the memory device 200) including the semiconductor die (block 730).

The method 700 may include additional aspects, such as any single aspect or any combination of aspects described below and/or in connection with one or more other methods described elsewhere herein.

Although FIG. 7 shows example blocks of the method 700, in some implementations, the method 700 may include additional blocks, fewer blocks, different blocks, or differently arranged blocks than those depicted in FIG. 7. In some implementations, the method 700 may include forming the stress reduction structure 150 and/or the semiconductor substrate 145.

FIGS. 8A through 8G are diagrammatic views showing formation of an annular stress reduction structure (e.g., the stress reduction structure 150-2) described at stages of an example process 800 described herein. In some implementations, the process 800 described below in connection with FIG. 8A through FIG. 8G may correspond to the method 500, one or more blocks of the method 500, the method 600, and/or one or more blocks of the method 600. However, the process described below is an example, and other example processes may be used to form the stress reduction structure, an integrated assembly that includes the stress reduction structure, and/or one or more parts of an integrated assembly including the stress reduction structure.

As shown in FIG. 8A, the process 800 may include forming (e.g., depositing or growing) the passivation region 335 over and/or on the interconnect region 330. The passivation region 335 may comprise, consist of, or consist essentially of one or more layers of a dielectric material such as nitride. Alternatively, the passivation region 335 may comprise, consist of, or consist essentially of one or more layers of another suitable dielectric material such as oxide, among other examples.

In some implementations, the passivation region 335 may oxidize (e.g., nitride in the passivation region 335 may have an oxidized surface) and, due to a volume expansion, induce a lateral compressive stress 805. However, and as described in greater detail in connection with FIGS. 8B through 8G, one or more operations used to form the stress reduction structure (e.g., the stress reduction structure 150-2) may alleviate and/or reduce the lateral compressive stress 805.

As shown in FIG. 8B, the process 800 may include forming (e.g., depositing) a layer of masking material 810 over and/or on the passivation region 335. The layer of masking material 810 may comprise, consist of, or consist essentially of photoresist, among other examples.

As shown in FIG. 8C, the process 800 may include patterning the layer of masking material 810 and forming a cavity 815 that penetrates through the layer of masking material 810 and through the passivation region 335 to the interconnect region 330. Patterning the layer of masking material 810 may include using a lithography operation that exposes, develops, and removes a portion of the layer of masking material 810. Additionally, or alternatively, forming the cavity 815 may include using a dry etching operation or another suitable removal operation that removes a portion of the passivation region 335. In some implementations, the cavity 815 has an approximately rectangular cross section. Additionally, or alternatively, in some implementations, the cavity 815 is annular (e.g., a ring-shaped cavity or an annular cavity) and is centered about the central axis of the semiconductor substrate 145.

In some implementations, formation and/or a presence of the cavity 815 may reduce and/or alleviate a stress condition in the passivation region 335 (e.g., the lateral compressive stress 805 as described in connection with FIG. 8A). Reducing and/or alleviating the stress condition may reduce a likelihood of the semiconductor wafer substrate warping and/or bowing.

As shown in FIG. 8D, the process 800 may include removing the layer of masking material 810. Removing the layer of masking material 810 may include using a stripping operation, an ashing operation, a dry etching operation, or another suitable removal operation, among other examples.

As shown in FIG. 8E, the process 800 may include forming (e.g., depositing or growing) a layer of semiconductive material 820 over and/or on the passivation region 335. In some implementations, and as shown in FIG. 8E, forming the layer of semiconductive material 820 over and/or on the passivation region 335 includes filling the cavities 815. The layer of semiconductive material 820 may comprise, consist of, or consist essentially of a semiconductive material such as porous silicon carbide. Alternatively, the layer of semiconductive material 820 may comprise, consist of, or consist essentially of another suitable semiconductive material.

In some implementations, forming the layer of semiconductive material 820 includes using a physical vapor deposition (PVD) operation. Additionally, or alternatively, in some implementations, forming the layer of semiconductive material 820 includes using a plasma enhanced physical vapor deposition (PECVD) operation. Additionally, or alternatively, in some implementations, forming the layer of semiconductive material 820 includes diffusing atoms from the layer of semiconductive material 820 into the substrate region 315 to fill voids and epitaxially grow the nanocrystal structures 405 (e.g., porous silicon carbide nanocrystal structures) in the substrate region 315.

As shown in FIG. 8F, the process 800 may include removing the layer of semiconductive material 820. In some implementations, removing the layer of semiconductive material 820 includes using a CMP operation. In such an implementation, the CMP operation may use a slurry that includes a compound element with abrasive properties. The compound element may include aluminum dioxide, silica, ceria, or another combination of elements that has suitable abrasive properties, among other examples.

As further shown in FIG. 8F, removing the layer of semiconductive material 820 renders the stress reduction structure 150-2. In some implementations, a discontinuity between the stress reduction structure 150-2 and the passivation region 335 (e.g., between the stress reduction structure 150-2 and a wall of the cavity 815) may inhibit crack propagation in the passivation region 335, the stress reduction structure 150-2, and/or other regions of the semiconductor substrate 145.

Additionally, or alternatively, in some implementations, removing the layer of semiconductive material may include forming the composite particulates 425 proximate an upper surface of the passivation region 335. The composite particulates 425 may include a combination of compound elements from the layer of semiconductive material 820 and the slurry, such as porous silicon carbide and aluminum dioxide, among other examples.

As further shown in FIG. 8F, the process 800 may include removing the layer of semiconductive material 820. In some implementations, removing the layer of semiconductive material 820 includes using a CMP operation. In such an implementation, the CMP operation may use a slurry that includes a compound element with abrasive properties. The compound element may include aluminum dioxide, silica, ceria, or another compound element with suitable abrasive properties, among other examples.

As shown in FIG. 8G, the process 800 may include forming (e.g., depositing) the protective region 340 over and/or on the passivation region 335 and the stress reduction structure 150-2. The protective region 340 may include a layer of a polymer material that comprises, consists of, or consists essentially of polyimide. Alternatively, the protective region 340 may include one or more layers of another polymer material with suitable chemical resistivity, moisture resistivity, and/or mechanical robustness to protect underlying regions of the semiconductor substrate 145.

As indicated above, the process 800 described in connection with FIG. 8A through FIG. 8G is provided as an example. Other examples may differ from what is described with respect to FIG. 8A through FIG. 8G.

In some implementations, a semiconductor substrate includes an array of semiconductor dies; a polyimide layer over the array of semiconductor dies; a nitride layer between the array of semiconductor dies and the polyimide layer; and a stress reduction structure that is along an outer perimeter of the semiconductor substrate, that surrounds the array of semiconductor dies, and that penetrates through the nitride layer.

In some implementations, an integrated assembly includes a substrate; and a semiconductor die over the substrate, comprising: a passivation region, comprising: a dielectric material: a protective region on the passivation region, comprising: a polymer material; and a substrate region, wherein composite particulates proximate an interface joining the passivation region and the protective region comprise one or more compound elements that are absent from the polymer material and the dielectric material.

In some implementations, a method includes forming a passivation region on an interconnect region of a semiconductor substrate; forming a protective region on the passivation region; forming an annular cavity along a perimeter of the semiconductor substrate that penetrates through the protective region and through the passivation region to the interconnect region; and forming an annular stress reduction structure in the annular cavity.

In some implementations, a method includes forming a passivation region on an interconnect region of a semiconductor substrate; forming an annular cavity along a perimeter of the semiconductor substrate that penetrates through the passivation region to the interconnect region; and forming an annular stress reduction structure in the annular cavity.

In some implementations, a method includes receiving a semiconductor substrate that includes an annular stress reduction structure along a perimeter of the semiconductor substrate, wherein the annular stress reduction structure surrounds an array of semiconductor dies on the semiconductor substrate, and wherein the annular stress reduction structure penetrates through a passivation region of the semiconductor substrate; removing a semiconductor die from the array of semiconductor dies; and forming an integrated assembly including the semiconductor die.

The foregoing disclosure provides illustration and description but is not intended to be exhaustive or to limit the implementations to the precise forms disclosed. Modifications and variations may be made in light of the above disclosure or may be acquired from practice of the implementations described herein.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor substrate, comprising:
an array of semiconductor dies;
a polyimide layer over the array of semiconductor dies;
a nitride layer between the array of semiconductor dies and the polyimide layer; and
a stress reduction structure that is along an outer perimeter of the semiconductor substrate, that surrounds the array of semiconductor dies, and that penetrates through the nitride layer.

2. The semiconductor substrate of claim 1, wherein the stress reduction structure penetrates through the nitride layer to an interconnect region of the array of semiconductor dies.

3. The semiconductor substrate of claim 1, wherein the stress reduction structure further penetrates through the polyimide layer and is exposed at a top surface of the polyimide layer.

4. The semiconductor substrate of claim 1, wherein the stress reduction structure comprises:
porous silicon carbide.

5. The semiconductor substrate of claim 1, wherein the stress reduction structure is annular about a central axis of the semiconductor substrate.

6. The semiconductor substrate of claim 1, wherein the nitride layer comprises:
an oxidized surface.

7. The semiconductor substrate of claim 1, wherein a thickness of the nitride layer is included in a range of approximately 0.4 microns to approximately 0.6 microns.

8. The semiconductor substrate of claim 1, wherein the array of semiconductor dies comprises:
high bandwidth memory dies, or
NAND memory dies.

9. An integrated assembly, comprising:
a substrate; and
a semiconductor die over the substrate, comprising:
a passivation region, comprising:
a dielectric material:
a protective region on the passivation region, comprising:
a polymer material; and
a substrate region,
wherein composite particulates proximate an interface joining the passivation region and the protective region comprise one or more compound elements that are absent from the polymer material and the dielectric material.

10. The integrated assembly of claim 9, wherein the one or more compound elements comprise:
porous silicon carbide.

11. The integrated assembly of claim 9, wherein the one or more compound elements comprise:
aluminum dioxide.

12. The integrated assembly of claim 9, wherein the semiconductor die further comprises:
a substrate region comprising nanocrystal structures,
wherein the nanocrystal structures comprise porous silicon carbide.

13. The integrated assembly of claim 9, wherein the semiconductor die further comprises:
pillar structures comprising a liner layer,
wherein the liner layer comprises nitride, and
wherein a thickness of the liner layer is included in a range of approximately 0.4 microns to approximately 0.6 microns.

14. A method, comprising:
forming a passivation region on an interconnect region of a semiconductor substrate;
forming a protective region on the passivation region;
forming an annular cavity along a perimeter of the semiconductor substrate that penetrates through the protective region and through the passivation region to the interconnect region; and
forming an annular stress reduction structure in the annular cavity.

15. The method of claim 14, wherein forming the passivation region includes forming a nitride layer, and
wherein forming the protective region includes:
forming a polyimide layer.

16. The method of claim 14, wherein forming the annular cavity includes:
forming a layer of photoresist on the protective region,
forming a pattern of the annular cavity in the layer of photoresist; and
removing material from the protective region according to the pattern to form the annular cavity.

17. The method of claim 14, wherein forming the annular stress reduction structure in the annular cavity includes:
forming a layer of porous silicon carbide on the protective region,
wherein forming the layer of porous silicon carbide fills the annular cavity with porous silicon carbide.

18. The method of claim 17, wherein forming the layer of porous silicon carbide includes:
forming the layer of porous silicon carbide using a physical vapor deposition operation.

19. The method of claim 17, further comprising:
planarizing the layer of porous silicon carbide to expose a surface of the passivation region.

20. The method of claim 19, wherein planarizing the layer of porous silicon carbide includes:
planarizing the layer of porous silicon oxide using a chemical/mechanical planarization operation that uses a slurry.

21. The method of claim 20, wherein planarizing the layer of porous silicon carbide includes:
forming composite particulates proximate the surface of the passivation region,
wherein the composite particulates include porous silicon carbide combined with a compound element of the slurry.

22. A method, comprising:
forming a passivation region on an interconnect region of a semiconductor substrate;
forming an annular cavity along a perimeter of the semiconductor substrate that penetrates through the passivation region to the interconnect region; and
forming an annular stress reduction structure in the annular cavity.

23. The method of claim 22, wherein forming the annular stress reduction structure includes:
forming a layer of semiconductive material on the passivation region.

24. The method of claim 23, wherein forming the annular stress reduction structure includes:
planarizing the layer of semiconductive material using a chemical mechanical planarization operation that uses a slurry including aluminum dioxide.

25. The method of claim 23, wherein forming the layer of semiconductive material on the passivation region includes:
forming the layer of semiconductive material using a deposition operation that diffuses atoms from the layer of semiconductive material into an underlying substrate region to form nanocrystal structures in the underlying substrate region.
